(19) United States
(12) Patent Application Publication
(10) Pub. No.: US 2018/0130705 A1
(43) Pub. Date: May 10, 2018

(54) Delayed Via Formation in Electronic Devices

(71) Applicant: Corning Incorporated, Corning, NY (US)

(72) Inventors: Tian Huang, Painted Post, NY (US); Sean Mathew Garner, Elmira, NY (US)

(21) Appl. No.: 15/344,760

(22) Filed: Nov. 7, 2016

(51) Int. Cl. H01L 21/768; H01L 21/683

(52) U.S. Cl. CPC H01L 21/76877; H01L 21/6835; H01L 21/76802

(57) ABSTRACT

Embodiments are related to systems and methods for forming vias in a substrate, and more particularly to systems and methods for forming vias in a substrate with non-via processing intervening between via processing steps.

### FIELD OF THE INVENTION

Embodiments are related to systems and methods for forming vias in a substrate, and more particularly to systems and methods for forming vias in a substrate with non-via processing intervening between via processing steps.

### BACKGROUND

Manufacturing of electronics devices often involves forming vias within a substrate. Such via formation is performed using a number of steps in serial that result via formation at a desired location in the substrate. These vias may be formed in a substrate prior to forming other structures on the substrate, after all other structures on the substrate, or between formation of structures on a substrate. Forming the vias prior to forming other structures on the substrate can result in difficulty forming the other non-via structures which exhibit incompatibilities with prior formed vias. Alternatively, forming the vias after forming other non-via structures on the substrate can require relatively high via processing registration which may be expensive or in some cases not possible.

Hence, for at least the aforementioned reasons, there exists a need in the art for advanced systems and methods for manufacturing electronic devices.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 is a flow diagram showing a method in accordance with some embodiments of the present inventions for via formation;

FIGS. 2a-2g show a subset of processing steps including via pre-definition and formation consistent with the method shown in FIG. 1;

FIG. 3 is a flow diagram showing another method in accordance with various embodiments of the present inventions for via formation where via pre-definition is performed after formation of a first set of non-via structures and via formation is performed after formation of a second set of non-via structures;

FIGS. 4a-4d show a subset of processing steps including via pre-definition and formation consistent with the method shown in FIG. 3;

FIG. 5 is a flow diagram showing yet another method in accordance with one or more embodiments of the present inventions for via formation where via pre-definition is performed on a first side of a substrate followed by formation of a set of non-via structures on a second side of the substrate and via formation back on the first side of the substrate; and

FIGS. 6a-6e show a subset of processing steps including via pre-definition and formation consistent with the method shown in FIG. 5.

### DETAILED DESCRIPTION OF SOME EMBODIMENTS

Embodiments are related to systems and methods for forming vias in a substrate, and more particularly to systems and methods for forming vias in a substrate with non-via processing intervening between via processing steps.

Various embodiments provide methods for forming vias in a substrate. Such methods include: performing a via pre-definition on a substrate such that at least one deformation is created on at least one surface or within the bulk of the substrate; forming a non-via structure on the substrate after the via pre-definition; and forming a via in the substrate after forming the non-via structure on the substrate such that the via is formed in the substrate at a location corresponding to the deformation. A material of the substrate may include, but is not limited to, glass, ceramic, polymer, metal, or a combination of two or more of the aforementioned materials including, in some cases, multi-layer structures. The non-via structure may be any of a number of structures formed atop a substrate including, but not limited to, a well capable of receiving a fluidically assembled micro-element, a transistor, an electric contact, an optical device, and an electrically conductive trace.

In some instances of the aforementioned embodiments, the via pre-definition is performed on the substrate prior to formation of any non-via structure on the substrate. In particular cases, the via pre-definition is performed on the substrate prior to any other processing on the substrate. In one or more instances of the aforementioned embodiments, the via pre-definition includes using laser energy to create the at least one deformation on at least one surface or within the bulk of the substrate. In some instances of the aforementioned embodiments, forming the via is done either using a dry etching process, a wet etching process, or a combination of both a dry and wet etching process.

In various instances of the aforementioned embodiments, a ratio of an area of an opening of the via to an area of an opening of the deformation is at least 5:1. In particular instances of the aforementioned embodiments, a ratio of an area of an opening of the via to an area of an opening of the deformation is at least 3:1. In other instances, this ratio can be at least 10:1, 50:1, or 100:1. In some instances of the aforementioned embodiments, performing the via pre-definition on the substrate is done when the substrate is secured to a first substrate carrier or frame, and forming the via in the substrate is done when the substrate is secured to a second substrate carrier or frame. In some cases, the first substrate carrier or frame is associated with a first facility or processing line and the second substrate carrier or frame is associated with a second facility or processing line. In other instances, the substrate can be secured to a processing carrier or frame for both the via pre-definition as well as subsequent device or via processing steps. The substrate can also be free-standing. The via pre-definition steps can also be performed in roll-to-roll processing methods while the substrate is in web form.

Other embodiments provide methods for forming vias in a substrate that include: providing a substrate including at least one deformation at a first surface of the substrate or within the bulk; performing non-via related processing on a selected surface of the substrate; and forming a via in the substrate after performing the non-via related processing such that the via is formed in the substrate at a location corresponding to the deformation. A material of the substrate may include, but is not limited to, glass, ceramic, polymer, metal, or a combination of these materials. The substrate can be a multi-layered structure where the via predefinition occurs at any of its layers. The non-via related processing may result in a non-via structure on the selected surface of the substrate. Such a non-via structure may be any of a number of structures formed atop a substrate including, but not limited to, a well capable of receiving a fluidically assembled micro-element, a transistor, an electric contact, an optical device, a display element, a sensor, a photovoltaic element, a film layer, and an electrically conductive trace. The selected surface may be either of the first surface of the substrate or a second surface of the substrate.

In some instances of the aforementioned embodiments, during the forming the via in the substrate, the substrate is secured to a substrate carrier or frame such that the first surface of the substrate is exposed to processing. In some such instances where the selected surface of the substrate is the second surface of the substrate, the substrate is secured to the substrate carrier or frame such that the second surface of the substrate is exposed to processing during the performing non-via related processing on the selected surface of the substrate. In other such instances where the selected surface of the substrate is the first surface of the substrate, the substrate is secured to the substrate carrier or frame such that the first surface of the substrate is exposed to processing during the performing non-via related processing on the selected surface of the substrate.

In one or more instances of the aforementioned embodiments, performing the non-via related processing on the selected surface of the substrate results in a non-via structure on the selected surface of the substrate. In particular instances of the aforementioned embodiments, the methods further include performing via pre-definition to yield the at least one deformation at the first surface or within the bulk of the substrate. Such via pre-definition may include, but is not limited to, a laser based deformation process.

Yet other embodiments provide methods for forming vias in a substrate that include: securing a substrate to a first substrate carrier or frame; performing a laser based via pre-definition on the substrate when the substrate is secured to the first substrate carrier or frame such that at least one deformation is created at the surface of the substrate; removing the substrate from the first substrate carrier or frame and securing the substrate to a second substrate carrier or frame; forming a non-via structure on the substrate after the via pre-definition; and forming a via in the substrate when the substrate is secured to the second substrate carrier or frame such that the via is formed in the substrate at a location corresponding to the deformation. A material of the substrate may be, for example, glass, ceramic, polymer, metal, or a combination of these materials. The non-via structure may be any of a number of structures formed atop a substrate including, but not limited to, a well capable of receiving a fluidically assembled micro-element, a transistor, an electric contact, an optical device, a display element, a sensor or antenna, a photovoltaic element, a film layer, and an electrically conductive trace.

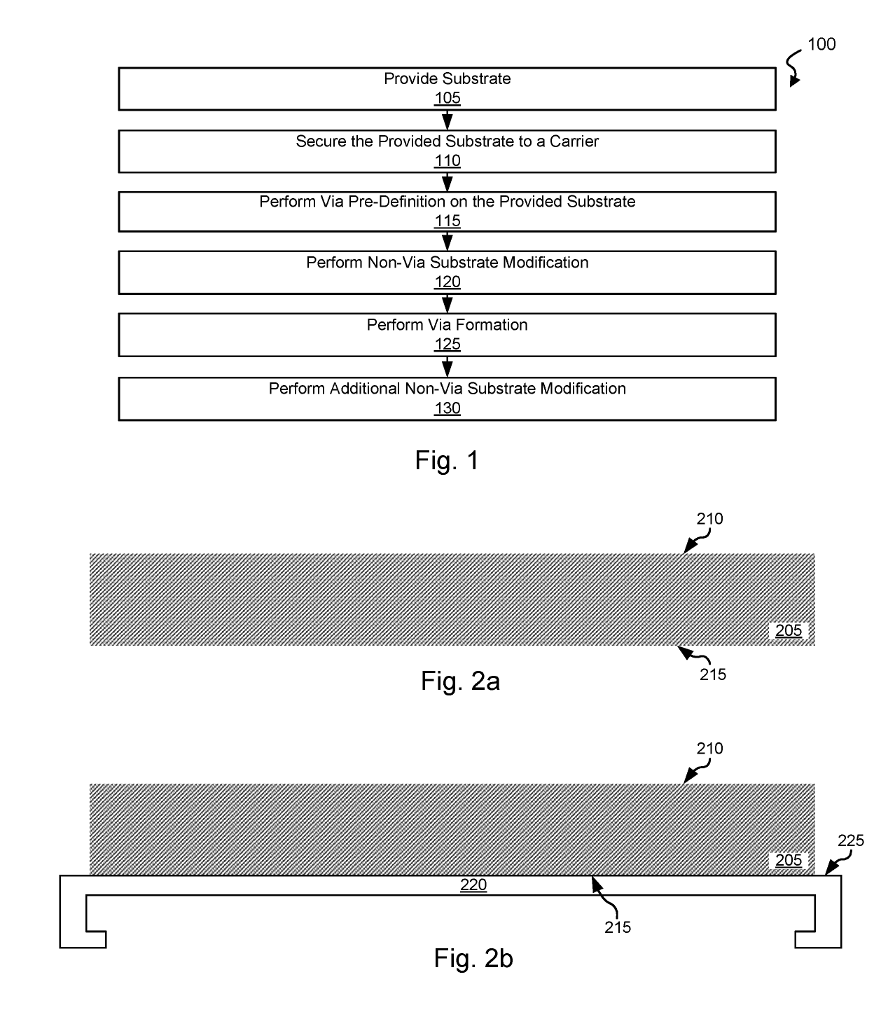

Turning to FIG. 1, a flow diagram 100 shows a method in accordance with some embodiments of the present inventions for via formation. Following flow diagram 100, a substrate is provided (block 105). The substrate may be any substrate or material suitable for device fabrication. As some examples, the substrate may be a glass substrate, glass-ceramic substrate, polymer substrate, metal substrate, or ceramic substrate. In some cases the substrate may be formed of a single material, while in other cases the substrate may consist of a composite of multiple materials or a multi-layer stack of different materials. In various cases the substrate is a rigid sheet, while in other cases the substrate is flexible and compatible with roll-to-roll processing. In one particular embodiment, the substrate is a Corning® EAGLE XG® sheet. In particular embodiments, the substrate is less than 0.7 mm thick. In one or more embodiments, the substrate is less than 0.5 mm thick. In other embodiments, the substrate is less than 0.3 mm thick. In some particular embodiments, the substrate is less than 0.1mm thick. Where thin film transistor (TFT) processing is to be performed, the substrate may be selected to be an alkali-free composition. Alternatively, where ion exchange processing is to be performed, the substrate may be selected to be an alkali-containing substrate. Based upon the disclosure provided herein, one of ordinary skill in the art will recognize a variety of substrates that may be used in relation to different embodiments. In various embodiments, the substrate can exhibit surface roughness value (Ra) of between less than one half nanometer (<0.5 nm) to one nanometer (1 nm). The substrate can have an area between 0.01 square meters (0.01 m²) and one square meter (1 m²). The substrate can be capable of device processing temperatures of greater than six hundred degrees Celsius (>600 C).

The provided substrate is secured to a substrate carrier (block 110). As used herein, the phrase “substrate carrier” is used in its broadest sense to mean any mechanism that may be used to secure a substrate for processing including, but not limited to, a substrate carrier or a processing frame. Based upon the disclosure provided herein, one of ordinary skill in the art will recognize a variety of mechanisms that may be used to secure a substrate in relation to different embodiments that would be considered “substrate carriers” in accordance with the definition above. In other embodiments, it is also possible to process the substrate without bonding it to a carrier. With the substrate secured by the substrate carrier, via pre-definition is performed on the provided substrate (block 115). As used herein, the phrase “via pre-definition” is used in its broadest sense to mean any process integral to forming a via in the substrate that results in less than full formation of the desired via in the substrate. This via pre-definition can be performed with any material or layer in a multi-layered substrate. As an example, via pre-definition may include modifying the substrate to mark or otherwise indicate a location where a via is to be formed. In various embodiments, via pre-definition includes creating a deformation at the location that a via is to be formed. In some such embodiments, via pre-definition includes creating a deformation at the location that a via is to be formed that is less than five (5) microns in diameter, and a subsequent via formation includes forming an opening in the substrate that is greater than five (5) microns in diameter. In other embodiments, via pre-definition includes creating a deformation at the location of a via that is less than three (3) microns in diameter, and a subsequent via formation includes forming an opening in the substrate that is greater than five (5) microns in diameter. In yet other embodiments, via pre-definition includes creating a deformation at the location of a via that is less than one (1) micron in diameter, and a subsequent via formation includes forming an opening in the substrate that is greater than five (5) microns in diameter. In particular embodiments, via pre-definition includes creating a deformation that is less than one-third of the size of the diameter of a via formed from a subsequent via formation. In other particular embodiments, via pre-definition includes creating a deformation that is less than one-fifth of the size of the diameter of a via formed from a subsequent via formation.

In one particular embodiment, via pre-definition is done by focusing a laser at locations on a surface of a substrate where vias are desired. The impact of the laser energy on the surface of the substrate results in a deformation on the surface of the substrate that can be used to guide subsequent processing steps including via formation. Examples of such laser based deformation processes that may be used to perform the aforementioned via pre-definition processes are set forth in US Pat. Pub. No. 2014/0199519 entitled “Method and Device for the Laser-Based Machining of Sheet-Like Substrates”, and filed Jan. 14, 2014 by Schillinger et al.; and US Pat. Pub. No. 2014/0199519 entitled “Method and Device for the Laser-Based Machining of Sheet-Like Substrates”, and filed Jan. 14, 2014 by Schillinger et al.; and US Pat. Pub. No. 2015/0166396 entitled “Method for Rapid Laser Drilling of Holes in Glass and Products Made Therefrom”, and filed Dec. 16, 2014 by Marjanovic et al. Each of the aforementioned references is incorporated herein by reference for all purposes. In one particular embodiment, a differential via pre-definition is performed where deformations exhibiting a diameter of less than three (3) microns are created on one side of the substrate, and deformations exhibiting a diameter of less than fifteen (15) microns are created on another side of the substrate. In yet another particular embodiment, the via pre-definition process includes creating deformations exhibiting a diameter of less than one (1) micron are created on both sides of the substrate. Based upon the disclosure provided herein, one of ordinary skill in the art will recognize a variety of processes that may be used to perform via pre-definition in accordance with different embodiments.

Non-via substrate modification is performed (block 120). As used herein, the phrase “non-via substrate modification” or alternatively “non-via processing” are used in the broadest sense to mean any process which modifies the substrate or surface thereof which is not an integral part of forming a via. As just some of many examples, non-via substrate modification may include, but is not limited to: patterning and forming a transistor on the substrate or some subset of the processes involved in such patterning and forming a transistor, patterning and forming a metalization layer on the substrate, fabricating physical structures such as wells or depressions used in fluidic assembly of display devices, ion exchanging of the substrate after via pre-definition, forming an active matrix backplane or passive matrix interconnect, fabricating sensor or antenna structures, fabricating photovoltaic structures, thermal cycling the substrate, vacuum or wet or mechanical processing of the substrate surface, creating a film or coating on the substrate surface, and/or fabricating an optical device on the surface of the substrate. Such non-via substrate modification includes any process performed that modifies the surface of the substrate that is not directly part of forming a via. Thus, for example, where a well structure is formed on a surface of the substrate which includes openings or wells extending into the substrate itself or defined in a layer formed on top of the substrate, such a process is not directly related to forming a via and is thus a non-via substrate modification. This is true even where the via locations defined as part of the via pre-definition extend from the bottom of the aforementioned openings or wells. In contrast, for example, where via pre-definition is performed by patterning and etching a mark in the surface of the substrate, that process of patterning and etching would be included in the via pre-definition which directly relates to the formation of a via and is thus not a non-via substrate modification.

Via formation is performed on the substrate (block 125). Via formation may include any process whereby a via is formed either completely or partially through the substrate to yield a completed via at locations corresponding to the deformations on the surface or within the bulk of the substrate created during the aforementioned via pre-definition. As such, the formed vias may be through-hole vias or blind vias. Such via formation may involve, for example, a dry or wet chemical etch process. It should be noted that any process known in the art for creating an opening in a substrate may be used in relation to embodiments so long as the process selected for performing via formation is compatible with any non-via substrate modification incurred between the via pre-definition and the via formation. This compatibility includes both: (1) the via formation process will not damage any non-via substrate modification, and (2) the via formation process will operate in the environment including the non-via substrate modification. After the vias are formed, processing on the substrate may be considered complete or additional non-via substrate modification may be performed (block 130).

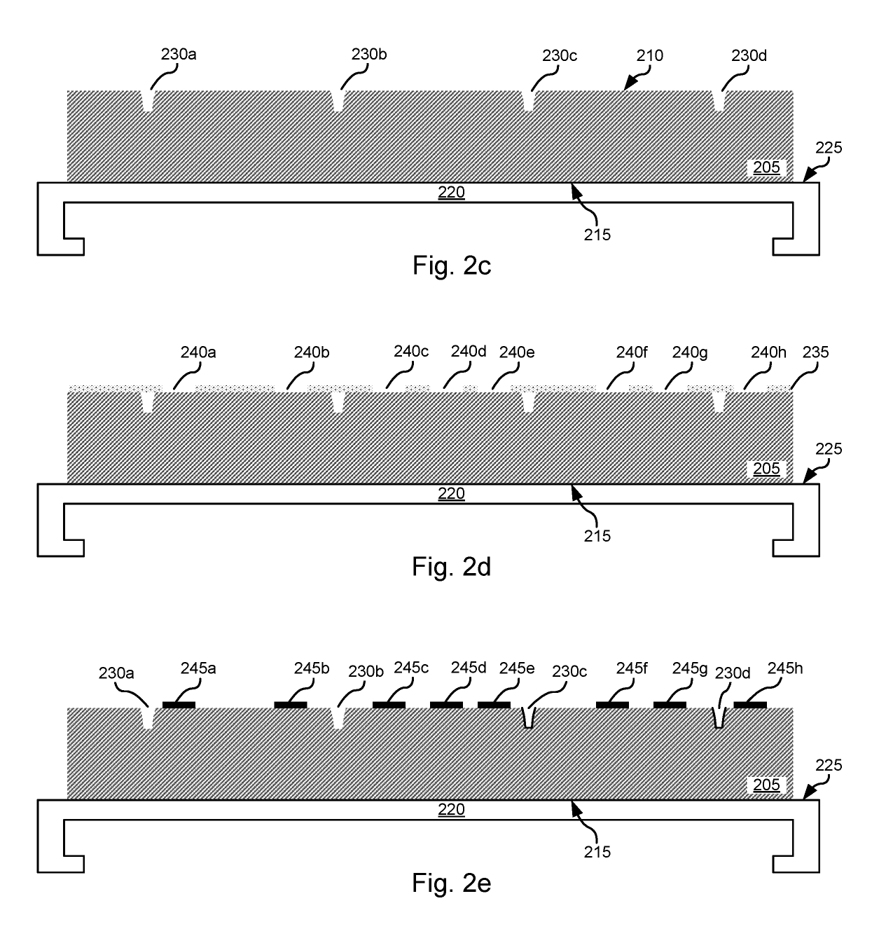

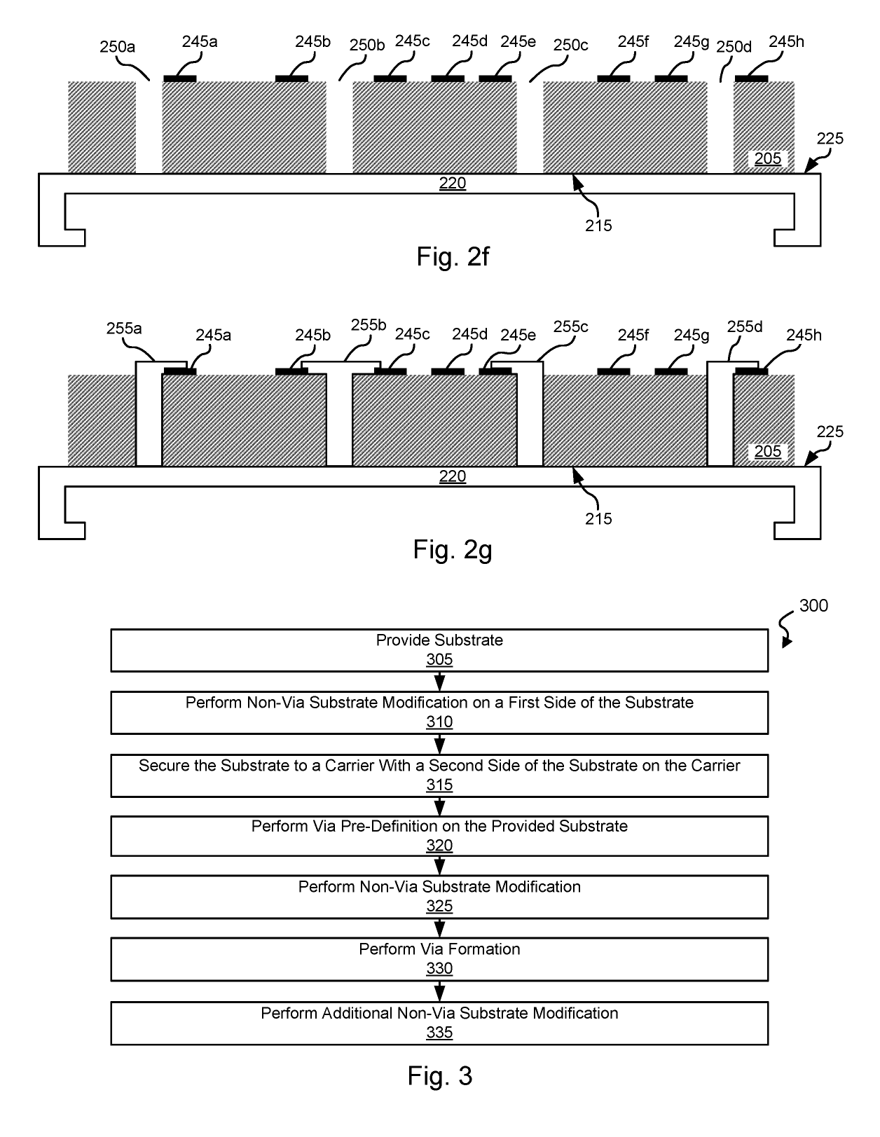

Turning to FIGS. 2a-2g, a subset of processing steps are shown including via pre-definition and formation consistent with the method discussed above in relation to FIG. 1. Turning to FIG. 2a, a substrate 205 is provided. Substrate 205 includes a first surface 210 and a second surface 215. As shown in FIG. 2b, substrate 205 is secured to a substrate carrier 225 such that second surface 215 is proximate a surface 225 of substrate carrier 220. As shown in FIG. 2c, a via pre-definition process is performed that results in a number of deformations 230 in first surface 210. As shown in FIGS. 2d-2e, non-via substrate modifications are performed that include forming a deposition pattern having openings 240 in a pattern layer 235 above first surface 210 of substrate 205. Subsequently, non-via structures 245 are formed within openings 240 and the remainder of pattern layer 235 is removed. It will be appreciated that the non-via substrate modifications shown in FIGS. 2d-2e are merely examples of many processes that may be performed after via pre-definition and prior to via formation. As shown in FIG. 2f, a via formation process is applied resulting in the formation of vias 250 at the locations corresponding to deformations 230. At this juncture the vias in substrate 205 are complete. Additional non-via substrate modification is performed by filling each of vias 250 with a material that extends over some of non-via structures 245.

By performing the via pre-definition prior to forming non-via structures on the substrate, the substrate at the locations where the via pre-definition is to be performed is untouched. Such an untouched substrate allows for increased accuracy of via locations when using, for example, the laser based deformation process discussed above. In contrast, where via pre-definition is performed after formation of one or more non-via structures on the substrate, residual from the processing steps used to form the non-via structures may be left on the substrate at locations where vias are to be formed which negatively impacts the ability to accurately perform the via pre-definition. It should be noted that in some cases via pre-definition may be performed after some non-via structures are formed on the substrate where care is used to limit the impact of such manufacturing steps on a later via pre-definition process.

In addition, by performing via formation after some of the processes used to form non-via structures have been completed, the previously completed processes are not negatively impacted by completed vias resulting from the via formation. For example, where forming the non-via structures includes vacuum deposition of thin films, such vacuum deposition would be negatively impacted where vias already extend through the substrate as the necessary vacuum may not be possible. As another example, spin casting of photoresist on the surface of the substrate may be negatively impacted where the substrate exhibits fully formed vias that are relatively larger than any deformations resulting from the via pre-definition. As yet another example, the optical exposure of photoresist on the surface of the substrate may be negatively impacted where the substrate exhibits fully formed vias that are relatively larger than any deformations resulting from the via pre-definition due to optical effects resulting from the larger openings.

Turning to FIG. 3, a flow diagram 300 shows another method in accordance with various embodiments of the present inventions for via formation where via pre-definition is performed after formation of a first set of non-via structures and via formation is performed after formation of an intervening second set of non-via structures. Following flow diagram 300, a substrate is provided (block 305). The substrate may be similar to that discussed above in relation to FIG. 1.

Non-via substrate modification is performed on a first side of the substrate (block 310). As just some of many examples, non-via substrate modification may include, but is not limited to: patterning and forming a transistor on the substrate or some subset of the processes involved in such patterning and forming a transistor, patterning and forming a metalization layer on the substrate, fabricating physical structures such as wells or depressions used in fluidic assembly of display devices, forming an active backplane or passive matrix interconnect, fabricating sensor or antenna structures, fabricating photovoltaic structures, thermal cycling the substrate, vacuum or wet or mechanical processing of the substrate surface, creating a film or coating on the substrate surface, and/or fabricating an optical device on the surface of the substrate. Such non-via substrate modification includes any process performed that modifies the surface of the substrate that is not directly part of forming a via. Thus, for example, where a well structure is formed on a surface of the substrate which includes openings or wells extending into the substrate itself or into a layer formed on top of the substrate such a process is not directly related to forming a via and is thus a non-via substrate modification. This is true even where the via locations defined as part of the via pre-definition extend from the bottom of the aforementioned openings of wells. In contrast, where, for example, via pre-definition is performed by patterning and etching a mark in the surface of the substrate, that process of patterning and etching would be included in the via pre-definition which directly relates to the formation of a via and is thus not a non-via substrate modification.

The provided substrate is secured to a substrate carrier with a second side of the substrate proximate to the substrate carrier (block 315). The substrate carrier may be any device or system that is capable of holding the substrate securely during processing. Based upon the disclosure provided herein, one of ordinary skill in the art will recognize a variety of substrate carriers that may be used in relation to different embodiments. Alternatively, the provided substrate can be secured to a substrate carrier with the first side of the substrate proximate to the substrate carrier.

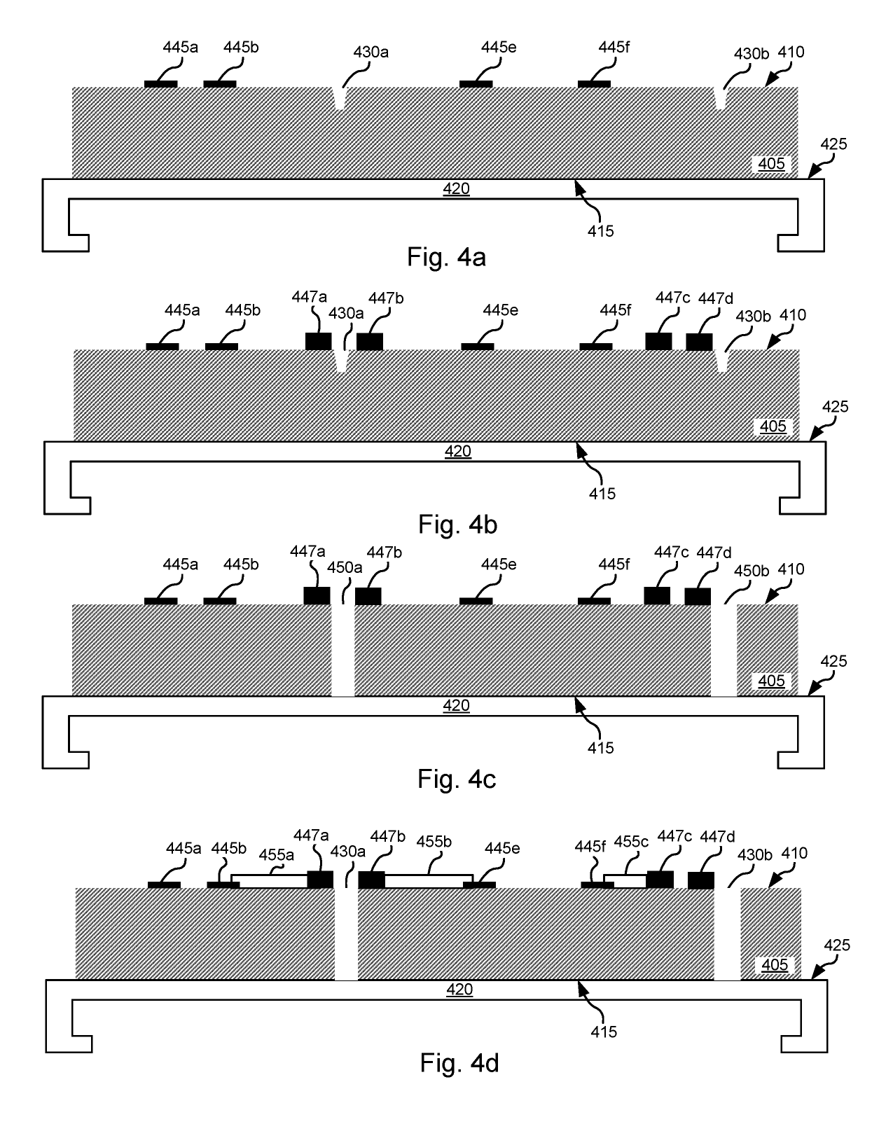

With the substrate secured by the substrate carrier, via pre-definition is performed on the first side of the provided substrate (block 320). As an example, via pre-definition may include modifying the substrate to mark or otherwise indicate a location where a via is to be formed. In various embodiments, via pre-definition includes creating a deformation at the location that a via is to be formed. Such via pre-definition may be performed similar to that discussed above in relation to FIG. 1. Turning to FIG. 4a, a substrate carrier 420 and a substrate 405 are shown after non-via substrate modification has been performed to yield non-via structures 445 and subsequent performance of via pre-definition to yield a number of deformations 430 in a first surface 410. A second surface 415 of substrate 405 is pressed against a top surface 425 of substrate carrier 420.

Returning to FIG. 3, subsequent to performing via pre-definition, additional non-via substrate modification is performed (block 325). Again, as just some of many examples, non-via substrate modification may include, but is not limited to: patterning and forming a transistor on the substrate or some subset of the processes involved in such patterning and forming a transistor, patterning and forming a metalization layer on the substrate, fabricating physical structures such as wells or depressions used in fluidic assembly of display devices, ion exchanging of the substrate after via pre-definition, forming an active backplane or passive matrix interconnect, and/or fabricating an optical device on the surface of the substrate. Such non-via substrate modification includes any process performed that modifies the surface of the substrate that is not directly part of forming a via. Turning to FIG. 4b, substrate 405 is shown after performance of the additional non-via substrate modification to yield non-via structures 447.

Returning to FIG. 3, via formation is performed on the substrate (block 330). Via formation may include any process whereby a via is formed either completely or partially through the substrate to yield a completed via at the deformations on the surface of the substrate that resulted from performing the aforementioned via pre-definition. As such, the formed vias may be through-hole vias or blind vias. Such via formation may involve, for example, a dry or wet chemical etch process. It should be noted that any process known in the art forming an opening in a substrate may be used in relation to embodiments so long as the process selected for performing via formation is compatible with any non-via substrate modification incurred between the via pre-definition and the via formation. This compatibility includes both: (1) the via formation process will not damage any non-via substrate modification, and (2) the via formation process will operate in the environment including the non-via substrate modification. Turning to FIG. 4c, substrate 405 is shown after performance of the via formation to open vias 450. Returning to FIG. 3, after the vias are formed, the substrate processing may be considered complete or may be followed by additional non-via substrate modification (block 335). Turning to FIG. 4d, substrate 405 is shown after performance of additional non-via substrate modification to form non-via structures 455.

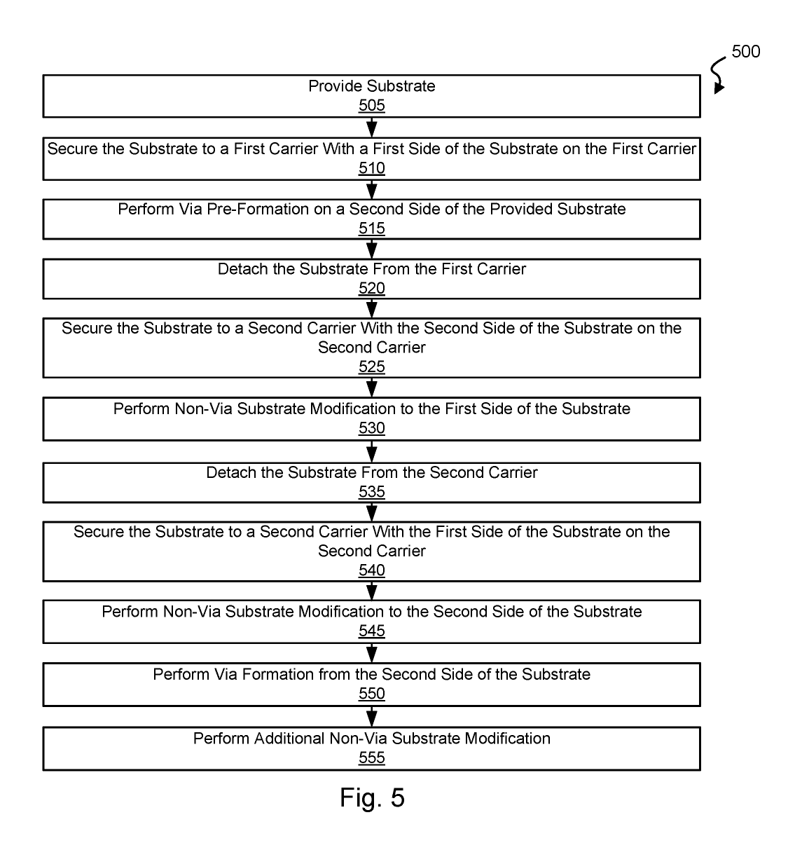

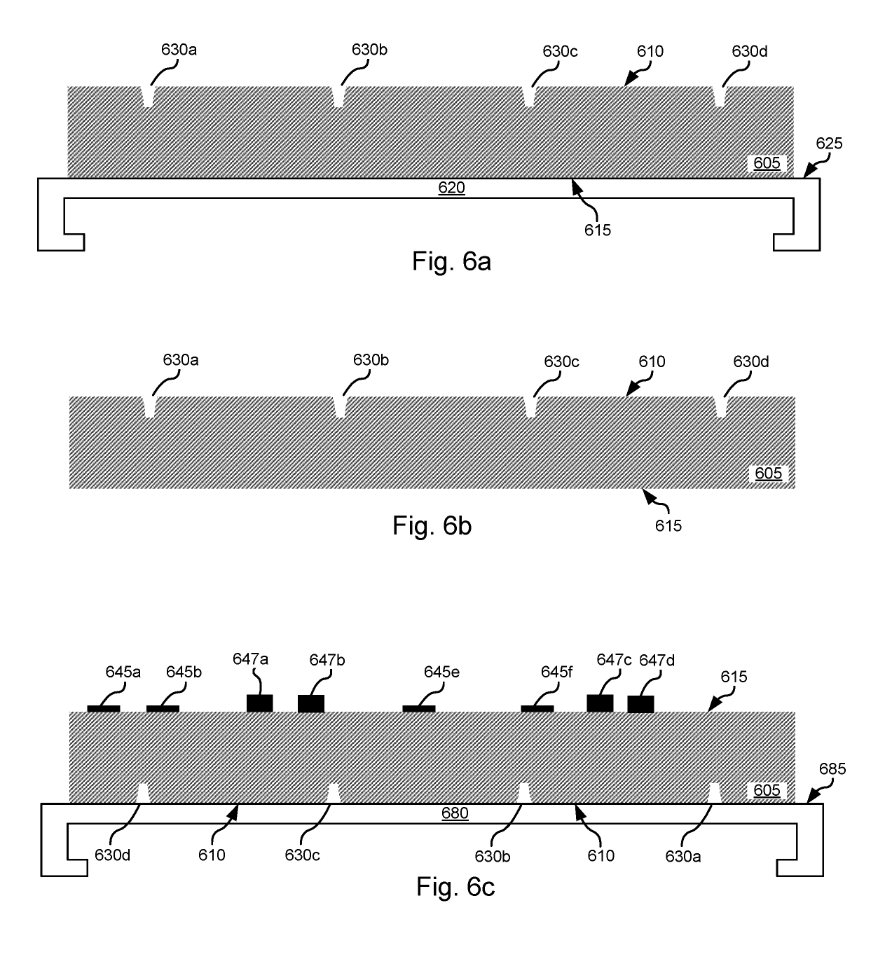

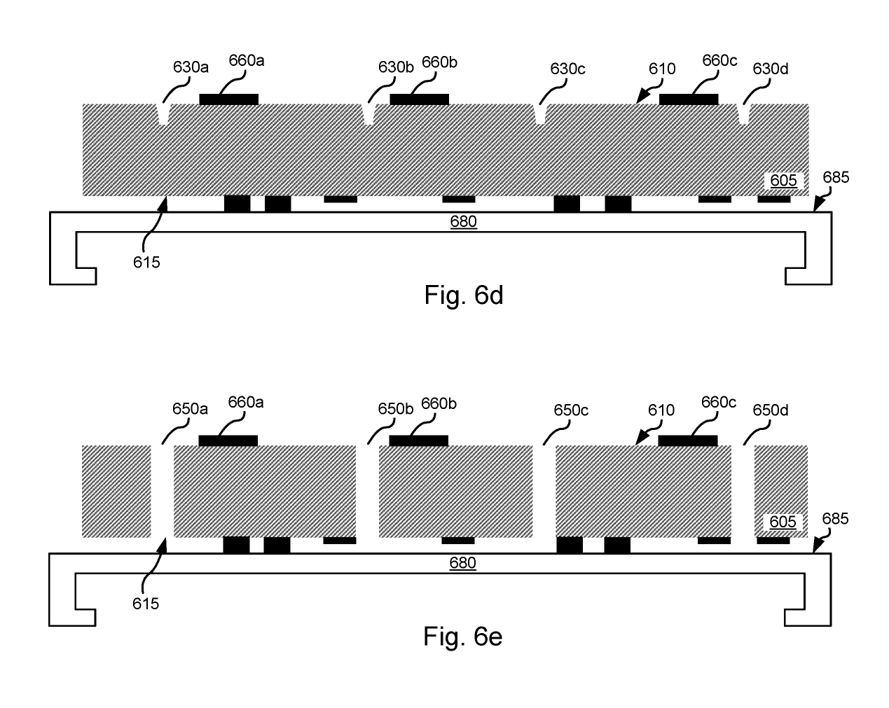

Turning to FIG. 5, a flow diagram 500 shows yet another method in accordance with one or more embodiments of the present inventions for via formation where via pre-definition is performed on a first side of a substrate followed by formation of a set of non-via structures on a second side of the substrate and via formation back on the first side of the substrate. Following flow diagram 500, a substrate is provided (block 505). The substrate may be similar to that discussed above in relation to FIG. 1. The substrate is secured to a first substrate carrier with a first side of the substrate on the first substrate carrier (block 510). Via pre-definition is the performed on the second side of the substrate (block 515). As an example, via pre-definition may include modifying the substrate to mark or otherwise indicate a location where a via is to be formed. In various embodiments, via pre-definition includes creating a deformation at the location that a via is to be formed. Such via pre-definition may be performed similar to that discussed above in relation to FIG. 1. Turning to FIG. 6a, a first substrate carrier 620 and a substrate 605 are shown after via pre-definition has been performed to yield a number of deformations 630 in a second surface 610 of substrate 605. A first surface 615 of substrate 605 is pressed against a top surface 625 of first substrate carrier 620.

Returning to FIG. 5, the substrate is then removed from the first substrate carrier (block 520). Turning to FIG. 6b, substrate 605 is shown detached from the first substrate carrier 620. Returning to FIG. 5, the substrate is attached to a second substrate carrier with the second side of the substrate on the second substrate carrier (block 525). By performing via pre-definition using a first substrate carrier followed by subsequent processing using a second substrate carrier, additional flexibility in processing can be achieved using a delayed via formation including a via pre-definition process separated from a via formation process by intervening non-via substrate modification. In particular, via pre-definition may be performed in one manufacturing facility or processing line using the first substrate carrier and further processing including via formation can be carried out in another manufacturing facility or processing line using the second substrate carrier.

Non-via substrate modification is performed on the first side of the substrate (block 530). As just some of many examples, non-via substrate modification may include, but is not limited to: patterning and forming a transistor on the substrate or some subset of the processes involved in such patterning and forming a transistor, patterning and forming a metalization layer on the substrate, fabricating physical structures such as wells or depressions used in fluidic assembly of display devices, forming an active backplane or passive matrix interconnect, fabricating sensor or antenna structures, fabricating photovoltaic structures, thermal cycling the substrate, vacuum or wet or mechanical processing of the substrate surface, creating a film or coating on the substrate surface, and/or fabricating an optical device on the surface of the substrate. Such non-via substrate modification includes any process performed that modifies the surface of the substrate that is not directly part of forming a via. Thus, for example, where a well structure is formed on a surface of the substrate which includes openings or wells extending into the substrate itself or into a layer formed on top of the substrate such a process is not directly related to forming a via and is thus a non-via substrate modification. This is true even where the via locations defined as part of the via pre-definition extend from the bottom of the aforementioned openings of wells. In contrast, where, for example, via pre-definition is performed by patterning and etching a mark in the surface of the substrate, that process of patterning and etching would be included in the via pre-definition which directly relates to the formation of a via and is thus not a non-via substrate modification. Turning to FIG. 6c, substrate 605 is shown attached to a second substrate carrier 680 with second side 610 against a surface 685 of second substrate carrier 680, and after formation of various non-via structures 645, 647 on first surface 615 of substrate 605.

Returning to FIG. 5, the provided substrate is detached from the second substrate carrier (block 535), and then re-secured to the second substrate carrier with the first side of the substrate toward the substrate carrier (block 540). In this configuration, the substrate is prepared for processing on the second side of the substrate. With the substrate secured by the second substrate carrier, non-via substrate modification is performed on the second side of the substrate (block 545). Turning to FIG. 6d, substrate 605 is shown attached to second substrate carrier 680 with first side 615 toward surface 685 of second substrate carrier 680, and after formation of various non-via structures 660 on second surface 610 of substrate 605.

Returning to FIG. 5, via formation is performed on the substrate (block 550). Via formation may include any process whereby a via is formed either completely or partially through the substrate to yield a completed via at the deformations on the surface of the substrate that resulted from performing the aforementioned via pre-definition. As such, the formed vias may be through-hole vias or blind vias. Such via formation may involve, for example, a dry or wet chemical etch process. It should be noted that any process known in the art forming an opening in a substrate may be used in relation to embodiments so long as the process selected for performing via formation is compatible with any non-via substrate modification incurred between the via pre-definition and the via formation. This compatibility includes both: (1) the via formation process will not damage any non-via substrate modification, and (2) the via formation process will operate in the environment including the non-via substrate modification. Turning to FIG. 6e, substrate 605 is shown after performance of the via formation to open vias 650. Returning to FIG. 5, after the vias are formed, the substrate processing may be considered complete or may be followed by additional non-via substrate modification (block 555).

In conclusion, the invention provides novel systems, devices, methods and arrangements for forming vias assembly. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

1. A method for forming vias in a substrate, the method comprising:
performing a via pre-definition on a substrate wherein at least one deformation is created that is visible at the surface of the substrate;
forming a non-via structure on the substrate after the via pre-definition; and
forming a via in the substrate after forming the non-via structure on the substrate such that the via is formed in the substrate at a location guided by the deformation.

2. The method of claim 1, wherein the via pre-definition is performed on the substrate prior to formation of any non-via structure on the substrate.

3. The method of claim 1, wherein the via pre-definition is performed on the substrate prior to any other processing on the substrate.

4. The method of claim 1, wherein the via pre-definition includes using laser energy to create the at least one deformation at the surface of the substrate.

5. The method of claim 1, wherein forming the via is done using an etching process.

6. The method of claim 5, wherein the etching process is selected from a group consisting of: a wet etch, and a dry etch.

7. The method of claim 1, wherein a ratio of an area of an opening of the via to an area of an opening of the deformation is at least 5:1.

8. The method of claim 1, wherein a ratio of an area of an opening of the via to an area of an opening of the deformation is at least 3:1.

9. The method of claim 1, wherein performing the via pre-definition on the substrate is done when the substrate is secured to a first substrate carrier, and wherein forming the via in the substrate is done when the substrate is secured to a second substrate carrier.

10. The method of claim 1, wherein a material of the substrate is selected from a group consisting of: glass, ceramic, polymer, metal, and a combination of two or more of glass, ceramic, polymer, and metal.

11. The method of claim 1, wherein the non-via structure is selected from a group consisting of: a well capable of receiving a fluidically assembled micro-element, a transistor, an electric contact, an optical device, a sensor structure, an antenna structure, a photovoltaic structure, a film or coating on the substrate surface, and an electrically conductive trace.

12. A method for forming vias in a substrate, the method comprising:
providing a substrate including at least one deformation at a first surface of the substrate;
performing non-via related processing on a selected surface of the substrate; and
forming a via in the substrate after performing the non-via related processing such that the via is formed in the substrate at a location selected using the deformation for alignment.

13. The method of claim 12, wherein the selected surface is selected from a group consisting of: the first surface, and a second surface.

14. The method of claim 12, wherein during the forming the via in the substrate, the substrate is secured to a substrate carrier such that the first surface of the substrate is exposed to processing.

15. The method of claim 14, wherein the selected surface of the substrate is a second surface of the substrate; and wherein during the performing non-via related processing on the selected surface of the substrate, the substrate is secured to the substrate carrier such that the second surface of the substrate is exposed to processing.

16. The method of claim 14, wherein the selected surface of the substrate is the first surface of the substrate; and wherein during the performing non-via related processing on the selected surface of the substrate, the substrate is secured to the substrate carrier such that the first surface of the substrate is exposed to processing.

17. The method of claim 12, wherein performing the non-via related processing on the selected surface of the substrate results in a non-via structure on the selected surface of the substrate.

18. The method of claim 17, wherein the non-via structure is selected from a group consisting of: a well capable of receiving a fluidically assembled micro-element, a transistor, an electric contact, an optical device, a sensor structure, an antenna structure, a photovoltaic structure, a film or coating on the substrate surface, and an electrically conductive trace.

19. The method of claim 12, wherein the method further comprises:
performing via pre-definition to yield the at least one deformation at the first surface of the substrate.

20. The method of claim 12, wherein forming the via is done using an etching process.

21. The method of claim 12, wherein a material of the substrate is selected from a group consisting of: glass, ceramic, and a combination of glass and ceramic.

22. (canceled)

23. A method for forming vias in a substrate, the method comprising:
performing a via pre-definition on a substrate wherein at least one deformation is created at the surface of the substrate;
forming a non-via structure on the substrate after the via pre-definition; and
forming a via in the substrate after forming the non-via structure on the substrate such that the via is formed in the substrate at a location corresponding to the deformation, wherein a ratio of an area of an opening of the via to an area of an opening of the deformation is at least 3:1.

24. The method of claim 1, wherein the substrate is made of a substrate material, and wherein forming the via in the substrate includes displacing a portion of the substrate material.

25. The method of claim 24, wherein displacing the portion of the substrate material includes removing at least some of the portion of the substrate material.

26. The method of claim 12, wherein the substrate is made of a substrate material, and wherein forming the via in the substrate includes displacing a portion of the substrate material.

27. The method of claim 26, wherein displacing the portion of the substrate material includes removing at least some of the portion of the substrate material.
